(19) United States
(12) Patent Application Publication
(10) Pub. No.: US 2026/0068054 A1
(43) Pub. Date: Mar. 5, 2026

(54) POWER MODULE

(71) Applicant: Delta Electronics, Inc., Taoyuan City (TW)

(72) Inventors: Yanbing Xia, Shanghai (CN); Dong Guo, Shanghai (CN); Baoping Li, Shanghai (CN)

(21) Appl. No.: 19/292,061

(22) Filed: Aug. 6, 2025

(30) Foreign Application Priority Data
Aug. 27, 2024 (CN) 202411182037.0

(51) Int. Cl. H05K 1/18; H01F 27/24; H01F 27/28; H05K 1/02

(52) U.S. Cl. CPC H05K 1/181; H01F 27/24; H01F 27/28; H05K 1/0203; H05K 2201/1003

(57) ABSTRACT

A power module is disclosed, and includes a semiconductor device, a magnetic component and a first circuit board. The magnetic component includes a magnetic core and a winding. The winding extends through the magnetic core. The semiconductor device, the magnetic component and the first circuit board are arranged in a stack along a first direction. The first side of the semiconductor device is welded on a side of the first circuit board. At least one of the lower surface of the magnetic component and the lower surface of the first circuit board forms a welding surface. The power module receives input signals from an exterior through the welding surface and transmits output signals to the exterior through the welding surface.

### CROSS-REFERENCE TO RELATED APPLICATION

This application claims priority to China Patent Application No. 202411182037.0, filed on Aug. 27, 2024. The entire contents of the above-mentioned patent application are incorporated herein by reference for all purposes.

### FIELD OF THE INVENTION

The present disclosure relates to an assembly structure of an electronic device, and more particularly to, a structure of a power module.

### BACKGROUND OF THE INVENTION

In order to cope with the increasing load power, the conventional structure of a power module is usually designed as follows: the semiconductor device is arranged at the top, the inductor is arranged in the middle, and the capacitor plate structure is arranged at the bottom. This conventional structure can effectively improve the power density to a certain extent. However, due to the limitations of the semiconductor devices, it is difficult to further reduce the volume of the entire structure. Therefore, it is difficult for the current power module to meet the requirements of applications requiring greater current density. On the other hand, as the size of the power module is reduced, it will inevitably bring about the heat dissipation problems.

Therefore, there is a need of providing a power module, for the existing applications that require a higher current density and a higher heat dissipation capability, so as to overcome the above drawbacks.

### SUMMARY OF THE INVENTION

An object of the present disclosure is to provide a power module. By vertically installing a magnetic component and a semiconductor device perpendicular to a welding surface, the area of the welding surface is reduced, thereby increasing the current density. In addition, the semiconductor device is connected to the magnetic component through the vias in the circuit board, and the heat generated by the entire power module is dissipated from the top of the magnetic component, thereby further improving the heat dissipation capacity of the power module.

In accordance with an aspect of the present disclosure, a power module is provided and includes a semiconductor device, a magnetic component and a first circuit board. The magnetic component includes a magnetic core and a winding, and the winding extends through the magnetic core. The semiconductor device, the magnetic component and the first circuit board are arranged in a stack along a first direction, a first side of the semiconductor device is welded on a side of the first circuit board, and at least one of a lower surface of the magnetic component and a lower surface of the first circuit board forms a welding surface. The power module receives input signals from an exterior through the welding surface and transmits output signals to the exterior through the welding surface.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a structural perspective view illustrating a power module according to a first embodiment of the present disclosure;

FIG. 2 is an exploded structural view illustrating the power module according to the first embodiment of the present disclosure;

FIG. 3 is an exploded structural view illustrating the power module according to the first embodiment of the present disclosure and taken from another perspective;

FIG. 4 is a schematic diagram showing the structure of the magnetic component according to the first embodiment of the present disclosure;

FIG. 5 is a schematic diagram showing a heat dissipation path of the power module according to the first embodiment of the present disclosure;

FIG. 6 is a structural perspective view illustrating a power module according to a second embodiment of the present disclosure;

FIG. 7 is a structural perspective view illustrating a power module according to a third embodiment of the present disclosure;

FIG. 8 is an exploded structural view illustrating the power module according to the third embodiment of the present disclosure;

FIG. 9 is an exploded structural view illustrating the power module according to the third embodiment of the present disclosure and taken from another perspective;

FIG. 10 is an exploded structural view illustrating a power module according to a fourth embodiment of the present disclosure;

FIG. 11 is a schematic diagram showing a heat dissipation path of the power module according to the fourth embodiment of the present disclosure; and

FIG. 12 is a structural perspective view illustrating a power module according to a fifth embodiment of the present disclosure.

### DETAILED DESCRIPTION

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed. In addition, the present disclosure may repeat reference numerals or letters in the various examples. This repetition is for the purpose of simplicity and clarity and does not in itself dictate a relationship between the various embodiments or configurations discussed. When an element is referred to as being “connected,” or “coupled,” to another element, it can be directly connected or coupled to the other element or intervening elements may be present. In addition, although the “first,” “second,” and the like terms in the claims be used to describe the various elements can be appreciated, these elements should not be limited by these terms, and these elements are described in the respective embodiments are used to express the different reference numerals, these terms are only used to distinguish one element from another element.

Some embodiments of the present disclosure are described in detail below with reference to the accompanying drawings. In the absence of conflict, the following embodiments and the features in the embodiments may be combined with each other, and the same or similar concepts or processes may not be described in detail in some embodiments.

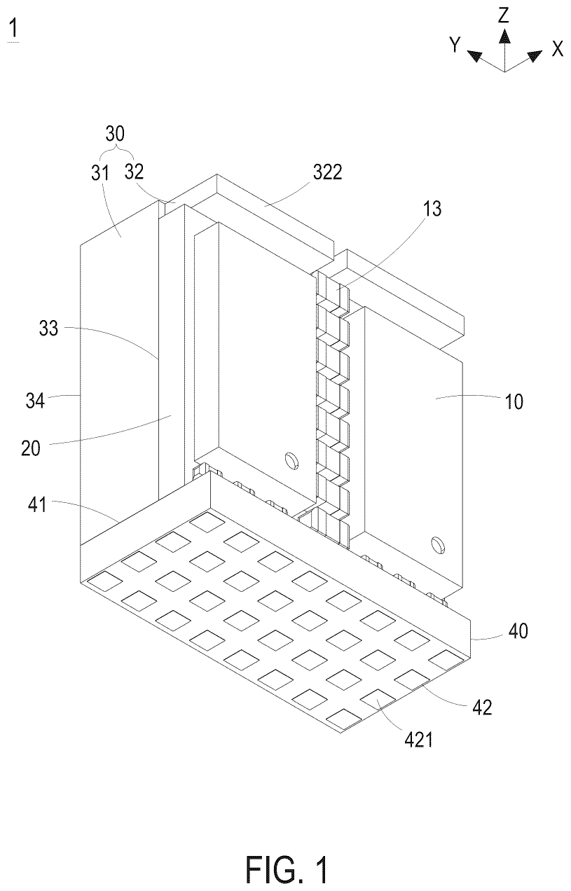

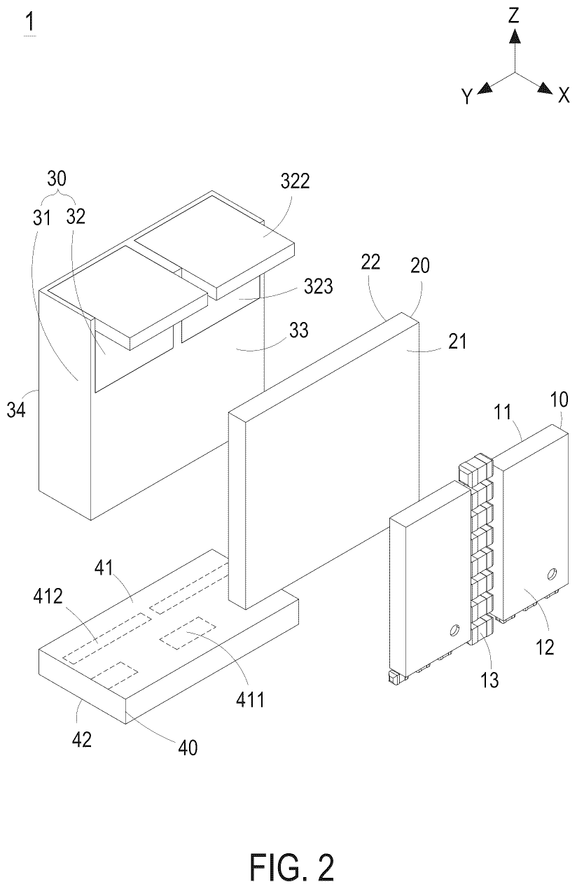

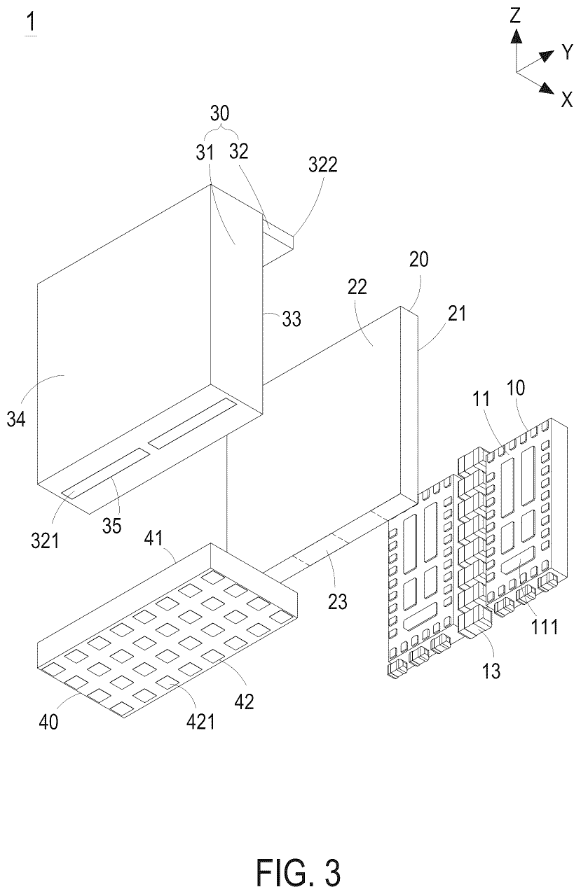

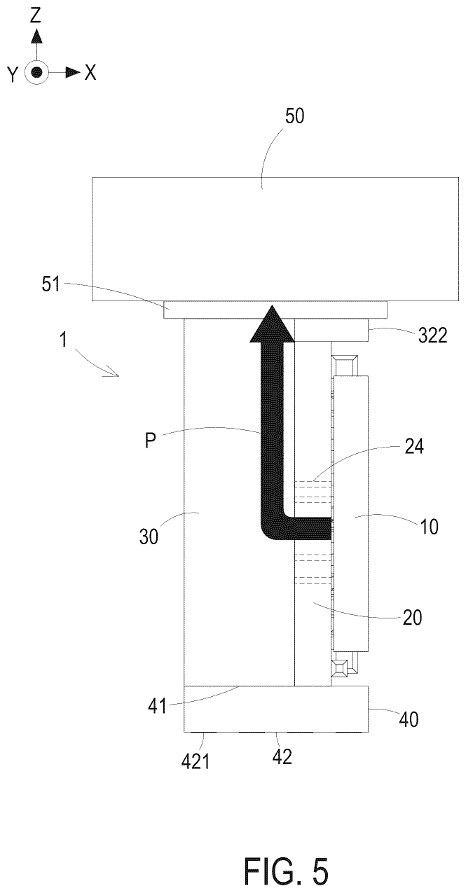

FIG. 1 is a structural perspective view illustrating a power module according to a first embodiment of the present disclosure. FIG. 2 is an exploded structural view illustrating the power module according to the first embodiment of the present disclosure. FIG. 3 is an exploded structural view illustrating the power module according to the first embodiment of the present disclosure and taken from another perspective. In the embodiment, the present disclosure provides a power module 1, includes a semiconductor device 10, a magnetic component 30, a first circuit board 20 and a second circuit board 40. Preferably but not exclusively, the semiconductor device 100 is a switching device, and the power module 1 may be applied to a voltage regulator. In the embodiment, the magnetic component 30 includes a magnetic core 31 and a winding 32, and the winding 32 extends through the magnetic core 31. The magnetic component 30, the first circuit board 20 and the semiconductor device 10 are arranged in a stack along a first direction, such as the X-axis direction. A first side 11 of the semiconductor device 10 is welded on a front side 21 of the first circuit board 20 through welding pads 111. Preferably but not exclusively, other electronic devices 13, such as capacitors, are disposed on the front side 21 of the first circuit board 20. In the embodiment, two semiconductor devices 10 are arranged side by side along the Y-axis direction. In other embodiments, a plurality of semiconductor devices 10 and other electronic devices 13 are arranged side by side on the front side 21 of the first circuit board 20 along the Y-axis direction. In addition, the semiconductor device 10 is further connected to the magnetic component 30 through vias 24 (refer to FIG. 5) in the first circuit board 20. Preferably but not exclusively, the vias 24 are metal vias. In the first direction (i.e., the X-axis direction), the first circuit board 20 is disposed between the magnetic component 30 and the semiconductor device 10. A rear side 22 of the first circuit board 20 is welded to a front side 33 of the magnetic component 30, and the semiconductor device 10 is connected to the magnetic component 30 through the metal vias 24 in the first circuit board 20. In the embodiment, a lower surface of the magnetic component 30 includes a welding region 35, and a lower surface of the first circuit board 20 includes a welding region 23. The welding region 35 is located between the front side 33 and the rear side 34 of the magnetic component 30. The welding region 23 corresponds to the welding pad 411 on the top side 41 of the second circuit board 40, and the welding region 35 corresponds to the welding pad 412 on the top side 41 of the second circuit board 40. The lower surface of the magnetic component 30 is coplanar with the lower surface of the first circuit board 20. The welding region 35 of the magnetic component 30 and the welding region 23 of the first circuit board 20 jointly form a welding surface. The power module 1 receives input signals from an exterior through the welding surface and transmits output signals to the exterior through the welding surface. Furthermore, the welding surface and the second circuit board 40 are arranged along a second direction, such as the Z-axis direction. The welding region 35 of the magnetic component 30 is welded to the welding pad 412 on the top side 41 of the second circuit board 40, and the welding region 23 of the first circuit board 20 is welded to the welding pad 411 on the top side 41 of the second circuit board 40. The first direction (i.e., the X-axis direction) and the second direction (i.e., the Z-axis direction) are perpendicular to each other. The structure of the power module 1 transmits electrical signals with the exterior through the conductive terminals 421 on the bottom side 42 of the second circuit board 40.

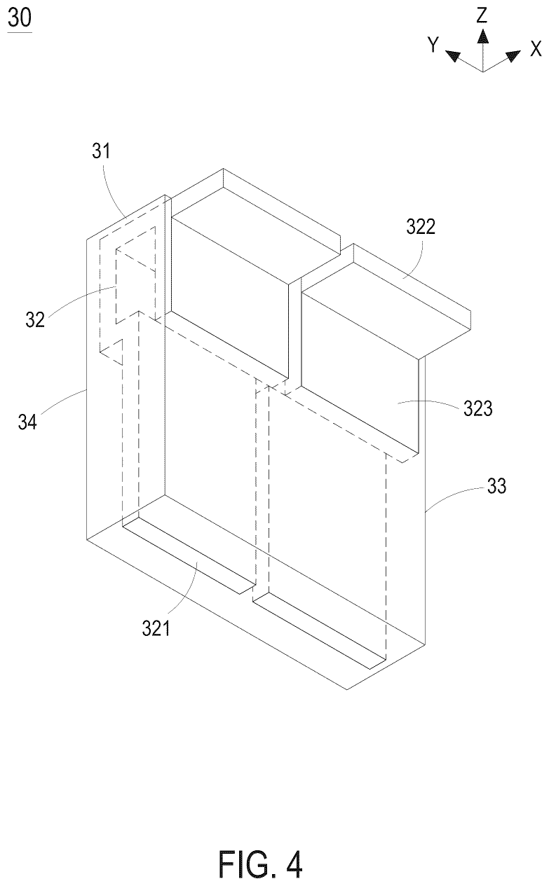

FIG. 4 is a schematic diagram showing the structure of the magnetic component according to the first embodiment of the present disclosure. Please refer to FIG. 1 and FIG. 4. In the embodiment, the winding 32 is partially embedded in the magnetic core 31. In the embodiment, a bottom end 321 of the winding 32 is exposed on the lower surface of the magnetic core 31 to form the welding region 35 of the magnetic component 30. That is, the bottom end 321 of the winding 32 forms a part of the welding surface. A top end 322 of the winding 32 is exposed on the upper surface of the magnetic core 31 and extended along the first direction (i.e., the X-axis direction) to provide a heat dissipation function. In addition, the winding 32 further includes an extension portion 323 extended from the top end 322 of the winding 32 along the second direction (i.e., the Z-axis direction), so as to be welded to the semiconductor device 10 or the first circuit board 20.

FIG. 5 is a schematic diagram showing a heat dissipation path of the power module according to the first embodiment of the present disclosure. Please refer to FIG. 1 to FIG. 5. In the embodiment, the top surface of the power module 1 is further connected to the heat dissipation device 50 through a thermal conductive material 51. Preferably but not exclusively, the thermal conductive material 51 includes a thermal interface material (TIM). Since the top end 322 of the winding 32 is exposed on the upper surface of the magnetic core 31, a heat dissipation path P is formed through the vias 24 in the first circuit board 20 and the winding 32 of the magnetic component 30 for the semiconductor device 10. The heat generated by the semiconductor device 10 is transferred to the top surface of the power module 1 through the winding 32 of the magnetic component 30 and dissipated through the heat dissipation device 50, thereby improving the heat dissipation capacity of the power module 1.

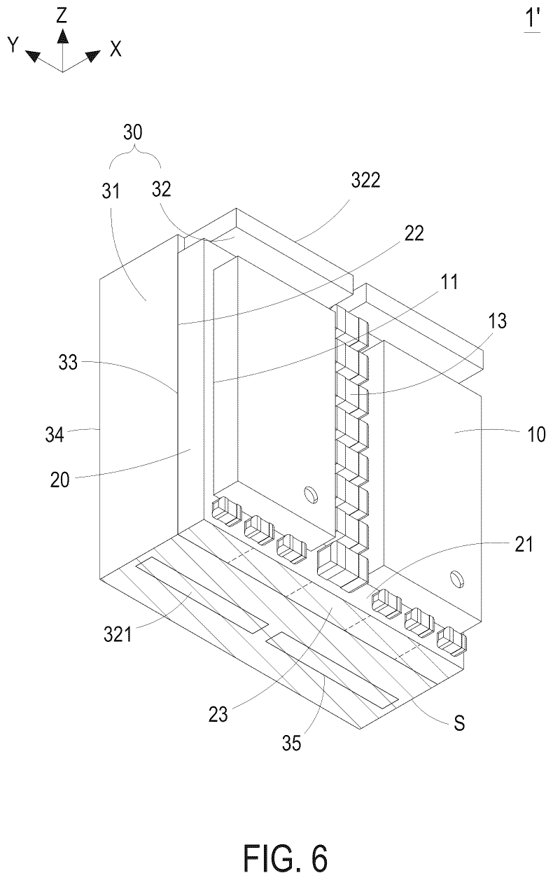

FIG. 6 is a structural perspective view illustrating a power module according to a second embodiment of the present disclosure. In the embodiment, the power module 1′ is similar to the power module 1 of FIG. 1 to FIG. 5, elements with same structures and functions are denoted with same symbols, and are not redundantly described herein. In the embodiment, the second circuit board 40 is further omitted in the power module 1′. In the first direction (i.e., the X-axis direction), the first circuit board 20 is further disposed between the magnetic component 30 and the semiconductor device 10. The first side 11 of the semiconductor device 10 is welded on the front side 21 of the first circuit board 20. The rear side 22 of the first circuit board 20 is welded to the extension portion 323 of the winding 32 of the magnetic component 30, so that the magnetic component 30, the first circuit board 20 and the semiconductor device 10 are sequentially arranged in a stack along the first direction (i.e., the X-axis direction) to form the power module 1′. In the embodiment, the lower surface of the magnetic component 30 includes the welding region 35, and the lower surface of the first circuit board 20 includes the welding region 23. The lower surface of the magnetic component 30 is coplanar with the lower surface of the first circuit board 20 to form the coplanar surface S, and the welding region 35 of the magnetic component 30 and the welding region 23 of the first circuit board 20 further jointly form the welding surface. The structure of the power module 1′ transmits electrical signals externally through the welding surface formed by the welding region 35 of the magnetic component 30 and/or the welding region 23 of the first circuit board 20.

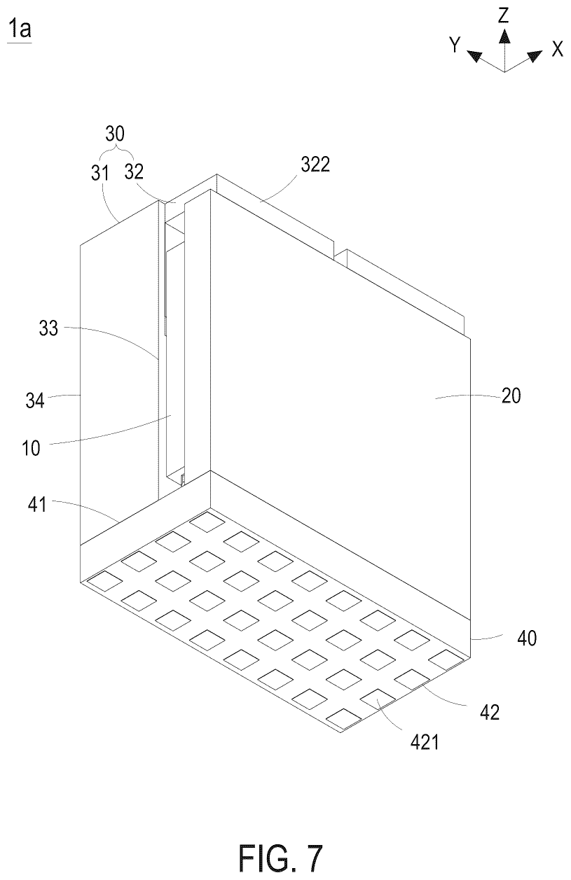

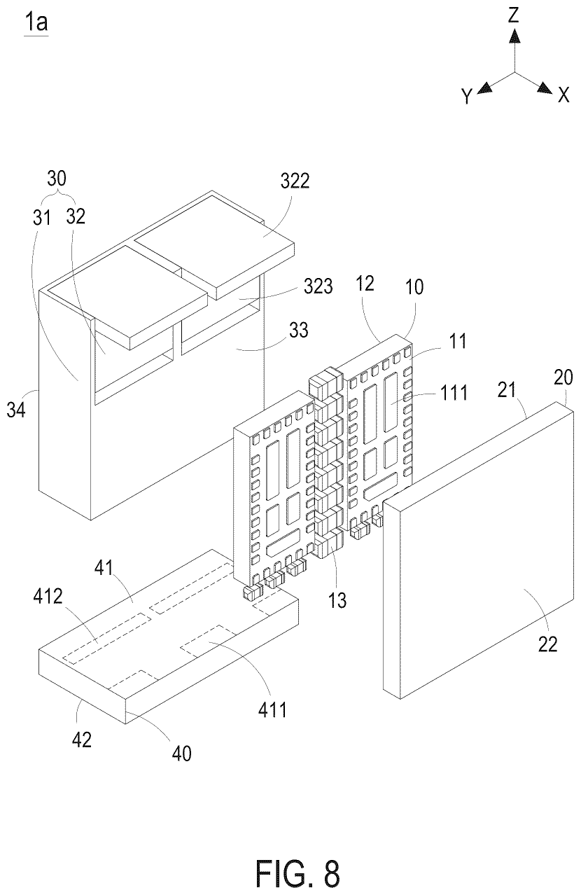

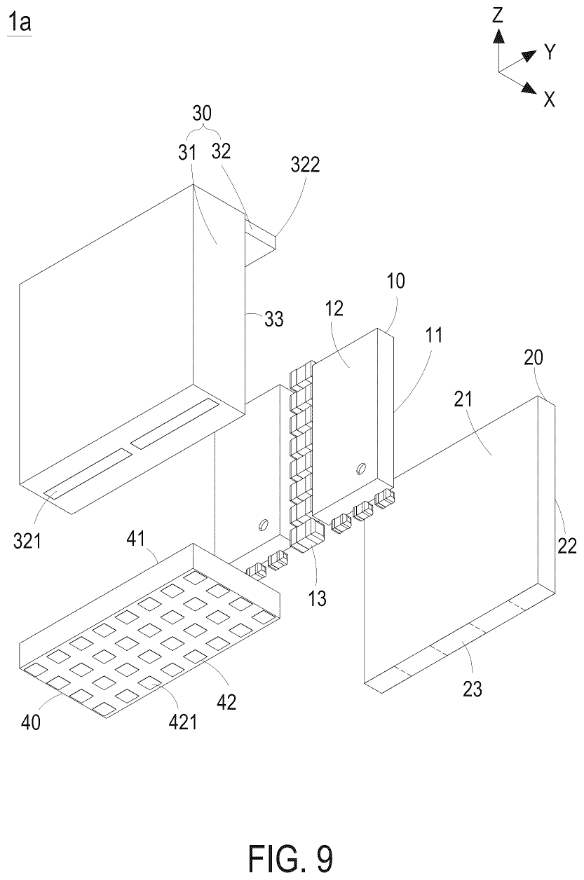

FIG. 7 is a structural perspective view illustrating a power module according to a third embodiment of the present disclosure. FIG. 8 is an exploded structural view illustrating the power module according to the third embodiment of the present disclosure. FIG. 9 is an exploded structural view illustrating the power module according to the third embodiment of the present disclosure and taken from another perspective. In the embodiment, the power module 1a is similar to the power module 1 of FIG. 1 to FIG. 5, elements with same structures and functions are denoted with same symbols, and are not redundantly described herein. In the embodiment, the power module 1a includes the magnetic component 30, the semiconductor device 10 and the first circuit board 20. The first side 11 of the semiconductor device 10 is welded to the front side 21 of the first circuit board 20 via the welding pad 111. In the first direction (i.e., the X-axis direction), the semiconductor device 10 is further disposed between the magnetic component 30 and the first circuit board 20. In the embodiment, the lower surface of the magnetic component 30 includes the welding region 35, and the lower surface of the first circuit board 20 includes the welding region 23. The lower surface of the magnetic component 30 is coplanar with the lower surface of the first circuit board 20. The welding region 35 of the magnetic component 30 and the welding region 23 of the first circuit board 20 jointly form the welding surface and are welded to the top side 41 of the second circuit board 40. The power module 1 transmits electrical signals with the exterior through the conductive terminals 421 on the bottom side 42 of the second circuit board 40.

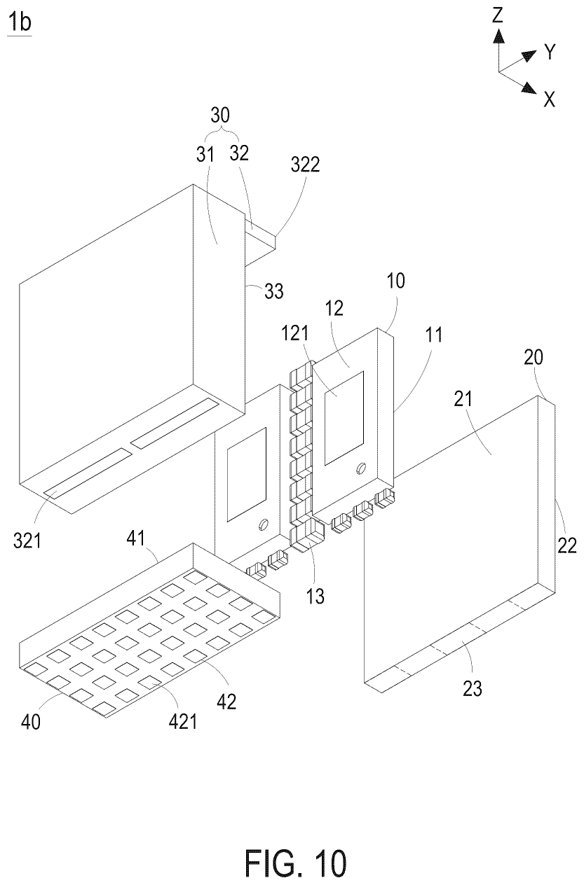

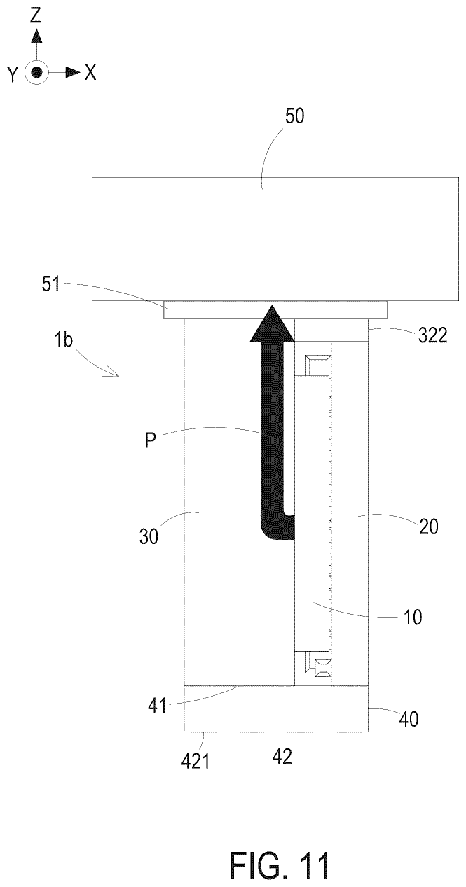

FIG. 10 is an exploded structural view illustrating a power module according to a fourth embodiment of the present disclosure. FIG. 11 is a schematic diagram showing a heat dissipation path of the power module according to the fourth embodiment of the present disclosure. In the embodiment, the power module 1b is similar to the power module 1a of FIG. 7 to FIG. 9, elements with same structures and functions are denoted with same symbols, and are not redundantly described herein. Similarly, in the embodiment, the semiconductor device 10 of the power module 1b is arranged between the magnetic component 30 and the first circuit board 20. The first side 11 of the semiconductor device 10 is welded to the front side 21 of the first circuit board 20 via the welding pad 111. In addition, the second side 12 of the semiconductor device 10 also includes the conductive terminal 121 welded to the magnetic component 30, and electrically connected to the extension portion 323 of the winding 32. The first side 11 and the second side 12 are two opposite sides of the semiconductor device 10. Thereby, the magnetic component 30, the semiconductor device 10 and the first circuit board 20 are sequentially arranged in a stack along the first direction (i.e., the X-axis direction). After the magnetic component 30, the semiconductor device 10 and the first circuit board 20 are assembled, the lower surface of the magnetic component 30 is coplanar with the lower surface of the first circuit board 20. At this time, the welding region 35 on the lower surface of the magnetic component 30 and the welding region 23 on the lower surface of the first circuit board 20 are welded to the top side 41 of the second circuit board 40. The power module 1b transmits electrical signals with the exterior through the conductive terminals 421 on the bottom side 42 of the second circuit board 40. In the embodiment, the top end 322 of the winding 32 is exposed on the upper surface of the magnetic core 31. When the top surface of the power module 1b is thermally connected to the heat dissipation device 50 through the thermal conductive material 51, a heat dissipation path P is directly formed through the winding 32 of the magnetic component 30 for the semiconductor device 10. That is, the heat generated by the semiconductor device 10 is dissipated to the heat dissipation device 50 through the winding 32 of the magnetic component 30, so as to further improve the heat dissipation capacity of the power module 1b.

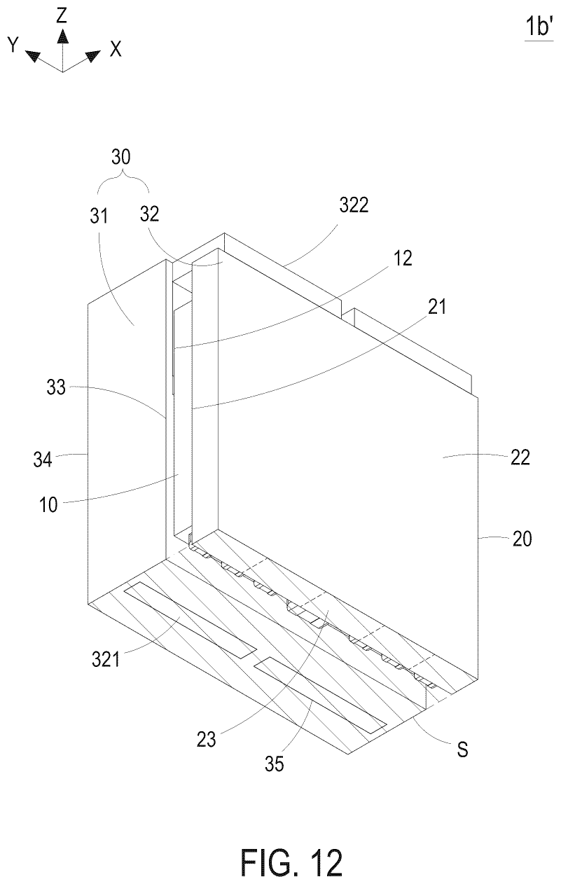

FIG. 12 is a structural perspective view illustrating a power module according to a fifth embodiment of the present disclosure. In the embodiment, the power module 1b′ is similar to the power module 1b of FIG. 10, elements with same structures and functions are denoted with same symbols, and are not redundantly described herein. In the embodiment, the second circuit board is further omitted in the power module 1b′. The first side 11 of the semiconductor device 10 is welded on the front side 21 of the first circuit board 20, and the second side 12 of the semiconductor device 10 is welded on the front side 33 of the magnetic component 30. The magnetic component 30, the semiconductor device 10 and the first circuit board 20 are arranged in a stack along the first direction (i.e., the X-axis direction) to form the power module 1b′. In the embodiment, the lower surface of the magnetic component 30 includes the welding region 35, and the lower surface of the first circuit board 20 includes the welding region 23. The lower surface of the magnetic component 30 is coplanar with the lower surface of the first circuit board 20 to form the coplanar surface S, and the welding region 35 of the magnetic component 30 and the welding region 23 of the first circuit board 20 further jointly form the welding surface. The power module 1b′ transmits the electrical signals with the exterior through the welding surface formed by the welding region 35 of the magnetic component 30 and the welding region 23 of the first circuit board 20.

From the above, the semiconductor device 10, the magnetic component 30, and the first circuit board 20 are horizontally stacked in the power modules 1, 1′, 1a, 1b, 1b′, allowing the power modules 1, 1′, 1a, 1b, 1b′ to transmit the electrical signals with the exterior through the welding surface. The size of the welding surface is determined by the thickness of the magnetic component 30, the first circuit board 20 and the semiconductor device 10, and is independent of the entire size or the count of the magnetic component 30, the first circuit board 20 and the semiconductor device 10. By vertically installing the magnetic component 30, the semiconductor device 10 and the first circuit board 20 perpendicular to the welding surface, the area of the welding surface is reduced, thereby improving the current density. On the other hand, the entire power module 1, 1′, 1a, 1b, 1b′ can dissipate the heat through the top surface of the magnetic component 30, improving the heat dissipation capacity of the power module 1, 1′, 1a, 1b, 1b′.

In each of the above embodiments, the bottom end 321 of the winding 32 of the magnetic component 30 is exposed on the lower surface of the magnetic core 31 to form the welding region 35 of the magnetic component 30.

In each of the above embodiments, when the first circuit board 20 is thick enough, it allows to fix the magnetic component 30 and the semiconductor device 10 on the first circuit board 20, and the welding surface is only formed by the welding region 23 on the lower surface of the first circuit board 20. The electrical signal is transmitted with the exterior through the welding surface formed by the lower surface of the first circuit board 20. Furthermore, if the corresponding power module includes the second circuit board 40, the external electrical signal is transmitted with the welding surface via the second circuit board 40.

In each of the above embodiments, when the magnetic component 30 is thick enough, the welding region 35 on the lower surface of the magnetic component 30 forms the welding surface. That is, only the lower surface of the magnetic component 30 form the welding surface, and the electrical signal is transmitted with the exterior through the welding surface. Furthermore, if the corresponding power module includes the second circuit board, the external electrical signal is transmitted with the welding surface via the second circuit board 40.

In summary, the present disclosure provides a power module. By vertically installing a magnetic component and a semiconductor device perpendicular to a welding surface, the area of the welding surface is reduced, thereby increasing the current density. In addition, the semiconductor device is connected to the magnetic component through the vias in the circuit board, and the heat generated by the entire power module is dissipated through the top of the magnetic component, so that the heat dissipation capacity of the power module is further improved.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power module, comprising:
a semiconductor device, a magnetic component and a first circuit board, wherein the magnetic component comprises a magnetic core and a winding, and the winding extends through the magnetic core, wherein the semiconductor device, the magnetic component and the first circuit board are arranged in a stack along a first direction, a first side of the semiconductor device is welded on a side of the first circuit board, and at least one of a lower surface of the magnetic component and a lower surface of the first circuit board forms a welding surface, wherein the power module receives input signals from an exterior through the welding surface and transmits output signals to the exterior through the welding surface.

2. The power module according to claim 1, wherein the power module further comprises a second circuit board welded to the welding surface, and the power module transmits signals with the exterior through the second circuit board.

3. The power module according to claim 1, wherein a top side of the power module is connected to a heat dissipation device, allowing heat generated by the semiconductor device to be transferred to the top side of the power module through the winding of the magnetic component and dissipated through the heat dissipation device.

4. The power module according to claim 3, wherein a top end of the winding is exposed on an upper surface of the magnetic core, extended along the first direction and connected to the heat dissipation device.

5. The power module according to claim 4, wherein the winding comprises an extension portion extended from the top end of the winding along a second direction and welded to the semiconductor device or the first circuit board, wherein the first direction is perpendicular to the second direction.

6. The power module according to claim 3, wherein the power module is connected to the heat dissipation device through a thermal conductive material.

7. The power module according to claim 1, wherein a bottom end of the winding is exposed on the lower surface of the magnetic core to form the welding surface.

8. The power module according to claim 1, wherein the semiconductor device is arranged between the magnetic component and the first circuit board.

9. The power module according to claim 1, wherein a second side of the semiconductor device is welded to the magnetic component, and the first side and the second side are two opposite sides of the semiconductor device.

10. The power module according to claim 1, wherein the first circuit board is arranged between the magnetic component and the semiconductor device, and another side of the first circuit board is welded to the magnetic component.

11. The power module according to claim 10, wherein the semiconductor device is connected to the magnetic component through metal vias in the first circuit board.

12. The power module according to claim 1, wherein the semiconductor device comprises a switching device, and the power module is applied to a voltage regulator.
